(19) United States
(12) Patent Application Publication
(10) Pub. No.: US 2015/0380299 A1
(43) Pub. Date: Dec. 31, 2015

(54) METHODS FOR PROVIDING SPACED LITHOGRAPHY FEATURES ON A SUBSTRATE BY SELF-ASSEMBLY OF BLOCK COPOLYMERS

(71) Applicant: ASML NETHERLANDS B.V., Veldhoven (NL)

(72) Inventors: Jozef Maria FINDERS, Veldhoven (NL); Sander Frederik WUISTER, Eindhoven (NL); Eddy Cornelis Antonius VAN DER HEIJDEN, Netersel (NL); Henri Marie Joseph BOOTS, Best (NL)

(21) Appl. No.: 14/768,423

(22) PCT Filed: Feb. 26, 2014
(86) PCT No.: PCT/EP2014/053694

§ 371 Date: Aug. 17, 2015

Related U.S. Application Data
(60) Provisional application No. 61/792,117, filed on Mar. 15, 2013.

(51) Int. Cl. H01L 21/768; G03F 7/20; H01L 21/3105; H01L 21/268; H01L 21/02; H01L 21/311

(52) U.S. Cl. CPC H01L 21/76816; H01L 21/02345; H01L 21/31133; H01L 21/31058; H01L 21/268; G03F 7/2004; G03F 7/2002

(57) ABSTRACT

A method of forming a plurality of regularly spaced lithography features, e.g. contact holes, including: providing a trench on a substrate, the trench having opposing side-walls and a base, with the side-walls having a width therebetween, wherein the trench is formed by photolithography including exposing the substrate using off-axis illumination whereby a modulation is provided to the side-walls of the trench; providing a self-assemblable block copolymer having first and second blocks in the trench; causing the self-assemblable block copolymer to self-assemble into an ordered layer in the trench, the layer having first domains of the first block and second domains of the second block; and selectively removing the first domain to form at least one regularly spaced row of lithography features having the second domain along the trench.

### CROSS-REFERENCE TO RELATED APPLICATIONS

This application claims the benefit of U.S. provisional application 61/792,117, which was filed on Mar. 15, 2013 and which is incorporated herein in its entirety by reference.

### FIELD

The present invention relates to a method of forming regularly spaced lithography features on a substrate, by use of self-assembly of a block copolymer in a trench on the substrate.

### BACKGROUND

In lithography for device manufacture, there is an ongoing desire to reduce the size of features in a lithographic pattern in order to increase the density of features on a given substrate area. Patterns of smaller features having critical dimensions (CD) at nano-scale allow for greater concentrations of device or circuit structures, yielding potential improvements in size reduction and manufacturing costs for electronic and other devices. In projection photolithography, the push for smaller features has resulted in the development of technologies such as immersion lithography and extreme ultraviolet (EUV) lithography.

As an alternative, so-called imprint lithography generally involves the use of a “stamp” (often referred to as an imprint template) to transfer a pattern onto a substrate. An advantage of imprint lithography is that the resolution of the features is not limited by, for example, the emission wavelength of a radiation source or the numerical aperture of a projection system. Instead, the resolution is mainly limited to the pattern density on the imprint template.

For both projection photolithography and for imprint lithography, it is desirable to provide high resolution patterning of surfaces, for example of an imprint template or of other substrates. The use of self-assembly of a block copolymers (BCP) has been considered as a potential method for increasing the feature resolution to a smaller dimension than that obtainable by prior lithography methods or as an alternative to electron beam lithography for preparation of imprint templates.

A self-assemblable BCP is a compound useful in nanofabrication because it may undergo an order-disorder transition on cooling below a certain temperature (order-disorder transition temperature To/d) resulting in phase separation of copolymer blocks of different chemical nature to form ordered, chemically distinct domains with dimensions of tens of nanometres or even less than 10 nm. The size and shape of the domains may be controlled by manipulating the molecular weight and composition of the different block types of the copolymer. The interfaces between the domains may have a line width roughness of the order of about 1-5 nm and may be manipulated by modification of the chemical compositions of the blocks of the copolymer.

The feasibility of using a thin film of BCP as a self-assembling template was demonstrated by Chaikin and Register, et al., Science 276, 1401 (1997). Dense arrays of dots and holes with dimensions of 20 nm were transferred from a thin film of poly(styrene-block-isoprene) to a silicon nitride substrate.

A BCP comprises different blocks, each typically comprising one or more identical monomers, and arranged side-by side along the polymer chain. Each block may contain many monomers of its respective type. So, for instance, an A-B BCP may have a plurality of type A monomers in the (or each) A block and a plurality of type B monomers in the (or each) B block. An example of a suitable BCP is, for instance, a polymer having covalently linked blocks of polystyrene (PS) monomer (hydrophobic block) and polymethylmethacrylate (PMMA) monomer (hydrophilic block). Other BCPs with blocks of differing hydrophobicity/hydrophilicity may be useful. For instance a tri-block copolymer such as (A-B-C) BCP may be useful, as may an alternating or periodic BCP e.g. [-A-B-A-B-A-B]ₙ or [-A-B-C-A-B-C]ₘ where n and m are integers. The blocks may be connected to each other by covalent links in a linear or branched fashion (e.g., a star or branched configuration).

A BCP may form many different phases upon self-assembly, dependent upon the volume fractions of the blocks, degree of polymerization within each block type (i.e. number of monomers of each respective type within each respective block), the optional use of a solvent and surface interactions. When applied in a thin film, geometric confinement may pose additional boundary conditions that may limit the phases formed. In general spherical (e.g. cubic), cylindrical (e.g. tetragonal or hexagonal) and lamellar phases (i.e. self-assembled phases with cubic, hexagonal or lamellar space-filling symmetry) are practically observed in thin films of self-assembled BCPs.

The phase type observed may depend upon the relative molecular volume fractions of the different polymer blocks. For instance, a molecular volume ratio of 80:20 may provide a cubic phase of discontinuous spherical domains of the low volume block arranged in a continuous domain of the higher volume block. As the volume ratio reduces to 70:30, a cylindrical phase may be formed with the discontinuous domains being cylinders of the lower volume block. At a 50:50 ratio, a lamellar phase may be formed. With a ratio of 30:70 an inverted cylindrical phase may be formed and at a ratio of 20:80, an inverted cubic phase may be formed.

Suitable BCPs for use as a self-assemblable polymer include, but are not limited to, poly(styrene-b-methylmethacrylate), poly(styrene-b-2-vinylpyridone), poly(styrene-b-butadiene), poly(styrene-b-ferrocenyldimethylsilane), poly(styrene-b-ethyleneoxide), poly(ethyleneoxide-b-isoprene). The symbol “b” signifies “block” Although these are di-block copolymer examples, it will be apparent that self-assembly may also employ a tri-block, tetra-block or other multi-block copolymer.

One method used to guide or direct self-assembly of a polymer (such as a BCP) onto a substrate surface is known as graphoepitaxy. This method involves the self-organization of a BCP guided by topological pre-patterning on the substrate using one or more features constructed of resist (or one or more features transferred from resist onto a substrate surface, or one or more features transferred onto a film stack deposited on the substrate surface). The pre-patterning is used to form an enclosure or “trench” comprising a substrate base and a sidewall, e.g., a pair of opposing side-walls, of resist (or a side-wall formed in a film or a side-wall formed in the substrate).

Typically, the height of a feature of a graphoepitaxy template is of the order of the thickness of the BCP layer to be ordered, so may be, for instance, from about 20 nm to about 150 nm.

A lamellar self-assembled BCP can form a parallel linear pattern of lithography features with adjacent lines of the different polymer block domains in the trenches. For instance if the BCP is a di-block copolymer with A and B blocks within the polymer chain, the BCP may self-assemble into an ordered layer in each trench, the layer comprising regularly spaced first domains of A blocks, alternating with second domains of B blocks.

Similarly, a cylindrical self-assembled BCP can form an ordered pattern of lithography features comprising regularly spaced parallel lines of cylindrical discontinuous first domains surrounded by a second continuous domain. For instance, if the BCP is a di-block copolymer with A and B blocks within the polymer chain, the A block may assemble into cylindrical discontinuous domains regularly spaced across the trench and surrounded by a continuous domain of B block.

Graphoepitaxy may be used, therefore, to guide the self-organization of lamellar or cylindrical phases such that the BCP pattern subdivides the spacing of the side wall(s) into domains of alternating copolymer patterns.

In a process to implement the use of BCP self-assembly in nanofabrication, a substrate may be modified with a neutral orientation control layer, as part of the graphoepitaxy template, to induce the preferred orientation of the self-assembly pattern in relation to the substrate. For some BCPs used in self-assemblable polymer layers, there may be a preferential interaction between one of the blocks and the substrate surface that may result in orientation. For instance, for a polystyrene(PS)-b-PMMA BCP, the PMMA block will preferentially wet (i.e. have a high chemical affinity with) an oxide surface and this may be used to induce the self-assembled pattern to lie oriented substantially parallel to the plane of the surface. Substantially normal orientation may be induced, for instance, by depositing a neutral orientation layer onto the surface rendering the substrate surface neutral to both blocks, in other words the neutral orientation layer has a similar chemical affinity for each block, such that both blocks wet the neutral orientation layer at the surface in a similar manner. By “normal orientation” it is meant that the domains of each block will be positioned side-by-side at the substrate surface, with the interfacial regions between adjacent domains of different blocks lying substantially perpendicular to the plane of the surface.

In a graphoepitaxy template for aligning a di-block copolymer having A and B blocks, where A is hydrophilic and B is hydrophobic in nature, the graphoepitaxy pattern may comprise hydrophobic resist side-wall features, with a neutral orientation base between the hydrophobic resist features. The B domain may preferentially assemble alongside the hydrophobic resist features, with several alternating domains of A and B blocks aligned over the neutral orientation region between the pinning resist features of the graphoepitaxy template.

A neutral orientation layer may, for instance, be created by use of random copolymer brushes which are covalently linked to the substrate by reaction of a hydroxyl terminal group, or some other reactive end group, to oxide at the substrate surface. In other arrangements for neutral orientation layer formation, a crosslinkable random copolymer or an appropriate silane (i.e. molecules with a substituted reactive silane, such as a (tri)chlorosilane or (tri)methoxysilane, also known as silyl, end group) may be used to render a surface neutral by acting as an intermediate layer between the substrate surface and the layer of self-assemblable polymer. Such a silane based neutral orientation layer will typically be present as a monolayer whereas a crosslinkable polymer is typically not present as a monolayer and may have a layer thickness of typically less than or equal to about 40 nm, or less than or equal to about 20 nm.

A thin layer of self-assemblable BCP may be deposited onto a substrate having a graphoepitaxy template as set out above. A suitable method for deposition of the self-assemblable polymer is spin-coating, as this process is capable of providing a well-defined, uniform, thin layer of self-assemblable polymer. A suitable layer thickness for a deposited self-assemblable polymer film is approximately 10 nm to 150 nm.

Following deposition of the BCP film, the film may still be disordered or only partially ordered and one or more additional steps may be needed to promote and/or complete self-assembly. For instance, the self-assemblable polymer may be deposited as a solution in a solvent, with solvent removal, for instance by evaporation, prior to self-assembly.

Self-assembly of a BCP is a process where the assembly of many small components (the BCP) results in the formation of a larger more complex structure (the nanometer sized features in the self-assembled pattern, referred to as domains in this specification). Defects arise naturally from the physics controlling the self-assembly of the polymer. Self-assembly is driven by the differences in interactions (i.e. differences in mutual chemical affinity) between A/A, B/B and A/B (or B/A) block pairs of an A-B BCP, with the driving force for phase separation described by Flory-Huggins theory for the system under consideration. The use of graphoepitaxy may greatly reduce defect formation.

For a polymer which undergoes self-assembly, the self-assemblable polymer will exhibit an order-disorder temperature To/d. To/d may be measured by any suitable technique for assessing the ordered/disordered state of the polymer, such as differential scanning calorimetry (DSC). If layer formation takes place below this temperature, the molecules will be driven to self-assemble. Above the temperature To/d, a disordered layer will be formed with the entropy contribution from disordered A/B domains outweighing the enthalpy contribution arising from favorable interactions between neighboring A-A and B-B block pairs in the layer. The self-assemblable polymer may also exhibit a glass transition temperature Tg below which the polymer is effectively immobilized and above which the copolymer molecules may still reorient within a layer relative to neighboring copolymer molecules. The glass transition temperature is suitably measured by differential scanning calorimetry (DSC).

Defects formed during ordering as set out above may be partly removed by annealing. A defect such as a disclination (which is a line defect in which rotational symmetry is violated, e.g. where there is a defect in the orientation of a director) may be annihilated by pairing with other another defect or disclination of opposite sign. Chain mobility of the self-assemblable polymer may be a factor for determining defect migration and annihilation and so annealing may be carried out at a temperature where chain mobility is high but the self-assembled ordered pattern is not lost. This implies temperatures up to a few ° C. above or below the order/disorder temperature To/d for the polymer.

Ordering and defect annihilation may be combined into a single annealing process or a plurality of processes may be used in order to provide a layer of self-assembled polymer such as BCP, having an ordered pattern of domains of differing chemical type (of domains of different block types).

In order to transfer a pattern, such as a device architecture or topology, from the self-assembled polymer layer into the substrate upon which the self-assembled polymer is deposited, typically a first domain type will be removed by so-called breakthrough etching to provide a pattern of a second domain type on the surface of the substrate with the substrate laid bare between the features of the second domain type. A pattern having parallel cylindrical phase domains can be etched using a dry etching or reactive ion etching technique. A pattern having lamellar phase domains can utilize a wet etching technique in addition to or as an alternative to those suitable for the etching of parallel cylindrical phase domains.

Following the breakthrough etching, the pattern may be transferred by so-called transfer etching using an etchant which is resisted by the second domain type and so forms recesses in the substrate surface where the surface has been laid bare.

### SUMMARY

Spacing between lithography features is known as pitch—defined as the width of one repeat unit of the lithography feature (i.e. feature width plus inter-feature spacing). A self-assembly process using a BCP can be used to produce lithography features with particularly low pitch, typically less than 30-50 nm.

It would be useful to be able to construct, using one processing step, multiple sets of lithography features, wherein the lithography features of one set are of different pitch to the lithography features of another set. Current methods require multiple processing steps (methods such as “pitch division” and “multi-patterning split” all require multiple processing steps).

It is an object of the invention, for example, to obviate or mitigate a disadvantage described herein, or some other disadvantage associated with the art, past, present or future.

According to an aspect, there is provided a method of forming a plurality of regularly spaced lithography features, the method comprising: providing a trench on a substrate, the trench comprising opposing side-walls and a base, with the side-walls having a width therebetween wherein the trench is formed by photolithography including exposing the substrate using off-axis illumination whereby a modulation is provided to the side-walls of the trench such that the width of the trench varies between minimum and maximum values along the length of the trench; providing a self-assemblable block copolymer having first and second blocks in the trench; causing the self-assemblable block copolymer to self-assemble into an ordered layer in the trench, the layer comprising first domains of first block and second domains of second block; and selectively removing the first domain to form at least one regularly spaced row of lithography features comprising the second domain along the trench.

In embodiments, the frequency of the modulation is controlled to match a desired pitch of the features. For example the frequency of the modulation may be controlled by varying the numerical aperture of a system providing the off-axis illumination. In an embodiment, the numerical aperture is in a range of from 1.1 to 1.35.

In an embodiment, the off-axis illumination is provided by quadrupole illumination. In an embodiment, the intensity of the modulation is controlled by varying the intensity ratio of two pairs of poles of the illumination. In an embodiment, the intensity ratio is in a range of from 1:20 to 1:200.

In an embodiment, the lithography feature comprises a contact hole.

In an embodiment, the side-walls of the trench are formed to have a higher chemical affinity for one of the block co-polymer blocks.

In an embodiment, the self-assemblable block co-polymer is adapted to form a regularly spaced row of the second domains surrounded by the first domain. In an embodiment, the first domain is removed by etching. In an embodiment, the first domain is removed by photo-degradation or photo-cleavage.

In an embodiment, the trench is formed by exposure using UV, EUV or DUV radiation.

The following features are applicable to all embodiments of the invention where appropriate. When suitable, combinations of the following features may be employed as part of an embodiment of the invention, for instance as set out in the claims. An embodiment of the invention is particularly suitable for use in device lithography. For instance, an embodiment of the invention may be of use in patterning a substrate which is used directly to form a device, or may be of use in patterning an imprint template for use in imprint lithography (which may then be used to form devices).

The substrate may be a semiconductor substrate, and may comprise a plurality of layers forming the substrate. For instance, the outermost layer of the substrate may be an ARC (anti-reflection coating) layer.

The outermost layer of the substrate may be neutral to the domains of the BCP, by which it is meant that it has a similar chemical affinity for each of the domain types of the BCP. The neutral orientation layer may, for example, be created by use of random copolymer brushes. An orientation control layer may be provided as an uppermost or outermost surface layer of the substrate to induce a desired orientation of the self-assembly pattern in relation to the substrate.

The trench comprising a pair of opposing side-walls may be formed by photolithography, for instance with actinic radiation such as UV, EUV or DUV (deep UV) radiation. The trench may, for example, be formed in resist. The trench may, for example, be formed on a substrate surface (e.g. having been transferred from resist onto the substrate). The trench may, for example, be formed in a film stack (e.g. having been transferred from resist onto the film stack).

The height of the trench may be of the order of the thickness of the BCP layer to be ordered. The height of the trench may, for example, be from about 20 nm to about 150 nm (e.g. about 100 nm). The trench may have a width of about 200 nm or less.

In order to direct self assembly and reduce defects, the side-walls may have a higher chemical affinity for one of the BCP domain types such that, upon assembly, the BCP domain type having the higher chemical affinity with the side-wall is caused to assemble alongside that side-wall. Chemical affinity may be provided by utilizing a hydrophobic or hydrophilic side-wall feature.

Providing the layer of self-assemblable BCP in the trench may be carried out by spin coating of a solution of the BCP followed by removal of solvent.

The self-assemblable BCP may be caused to self-assemble by increasing the temperature to a temperature less than To/d for the BCP, to give an ordered layer of self-assembled BCP in the trench. Typically, the annealing temperature is a temperature between To/d and Tg.

Selectively removing one of the domains may be achieved by etching, which may be wet or dry etching, wherein the ordered layer of self-assembled BCP acts as a resist layer for etching a row of regularly spaced lithography features along the trench on the substrate. Selective etching can be achieved by utilizing polymers having different etch resist properties and by selection of an etchant capable of selectively etching certain of the polymer domains. Selective removal may be achieved, for instance, by selective photo-degradation or photo-cleavage of a linking agent between blocks of the copolymer and subsequent solubilization of one of the blocks. Subsequent washing away of BCP fragments may be performed with, for example, a suitable acid.

A method according to an embodiment of the invention may be used in a process for the manufacture of devices, such as electronic devices and integrated circuits or other applications, such as the manufacture of integrated optical systems, guidance and detection patterns for magnetic domain memories, flat-panel displays, liquid-crystal displays (LCDs), thin film magnetic heads, organic light emitting diodes, etc. An embodiment of the invention may also be of use to create regular nanostructures on a surface for use in the fabrication of integrated circuits, bit-patterned media and/or discrete track media for magnetic storage devices (e.g. for hard drives).

An embodiment of a method described herein may be useful for forming high resolution features with better placement and pitch regularity.

The self-assemblable BCP may be a BCP as set out hereinbefore comprising at least two different block types, referred to as first and second polymer blocks, which are self-assemblable into an ordered polymer layer having the different block types associated into first and second domain types. The BCP may comprise di-block copolymer, a tri-block copolymer and/or a multi-block copolymer. Alternating or periodic BCPs may be used in the self-assemblable BCP.

By “chemical affinity”, in this specification, is meant the tendency of two differing chemical species to associate together. For instance chemical species which are hydrophilic in nature have a high chemical affinity for water whereas hydrophobic compounds have a low chemical affinity for water but a high chemical affinity for an alkane. Chemical species which are polar in nature have a high chemical affinity for other polar compounds and for water whereas apolar, non-polar or hydrophobic compounds have a low chemical affinity for water and polar species but may exhibit high chemical affinity for other non-polar species such as an alkane or the like. The chemical affinity is related to the free energy associated with an interface between two chemical species: if the interfacial free energy is high, then the two species have a low chemical affinity for each other whereas if the interfacial free energy is low, then the two species have a high chemical affinity for each other. Chemical affinity may also be expressed in terms of “wetting”, where a liquid will wet a solid surface if the liquid and surface have a high chemical affinity for each other, whereas the liquid will not wet the surface if there is a low chemical affinity. Chemical affinities of surfaces may be measured, for instance, by means of contact angle measurements using various liquids, so that if one surface has the same contact angle for a liquid as another surface, the two surfaces may be said to have substantially the same chemical affinity for the liquid. If the contact angles differ for the two surfaces, the surface with the smaller contact angle has a higher chemical affinity for the liquid than the surface with the larger contact angle.

By “chemical species” in this specification is meant either a chemical compound such as a molecule, oligomer or polymer, or, in the case of an amphiphilic molecule (i.e. a molecule having at least two interconnected moieties having differing chemical affinities), the term “chemical species” may refer to the different moieties of such molecules. For instance, in the case of a di-block copolymer, the two different polymer blocks making up the block copolymer molecule are considered as two different chemical species having differing chemical affinities.

Throughout this specification, the term “comprising” or “comprises” means including the component(s) specified but not to the exclusion of the presence of others. The term “consisting essentially of” or “consists essentially of” means including the components specified but excluding other components except for materials present as impurities, unavoidable materials present as a result of processes used to provide the components, and components added for a purpose other than achieving the technical effect of the invention. In an embodiment, a composition consisting essentially of a set of components will comprise less than 5% by weight, typically less than 3% by weight, more typically less than 1% by weight of non-specified components. The terms “consist of” or “consisting of” mean including the components specified but excluding the deliberate addition of other components.

In this specification, when reference is made to the thickness of a feature, the thickness is suitably measured by an appropriate means along an axis substantially normal to the substrate surface and passing through the centroid of the feature. Thickness may suitably be measured by a technique such as interferometry or assessed through knowledge of etch rate.

In this specification, the term “substrate” is meant to include any surface layer forming part of the substrate, or being provided on a substrate, such as one or more planarization layers or anti-reflection coating layers which may be at, or form, the surface of the substrate, or may include one or more other layers such as those specifically mentioned herein.

### BRIEF DESCRIPTION OF THE DRAWINGS

Specific embodiments of the invention will be described with reference to the accompanying Figures, in which:

FIG. 1 schematically depicts directed self-assembly of A-B block copolymer onto a substrate by graphoepitaxy and formation of regularly spaced lithography features by selective etching of one domain;

FIG. 2 schematically depicts and array of contact holes such as may be formed by an embodiment of the present invention;

FIG. 3 schematically illustrates a source of off-axis illumination as may be used in an embodiment of the invention;

FIG. 4 shows a resist pattern according to an embodiment of the invention;

FIG. 5 shows another resist pattern according to an embodiment of the invention;

FIGS. 6(a) and (b) show further resist patterns according to an embodiment of the invention; and

FIG. 7 shows an array of contact holes formed by means of a method according to an embodiment of the invention.

### DETAILED DESCRIPTION

The described and illustrated embodiments are to be considered as illustrative and not restrictive in character, it being understood that all changes and modifications that come within the scope of the inventions as defined in the claims are desired to be protected.

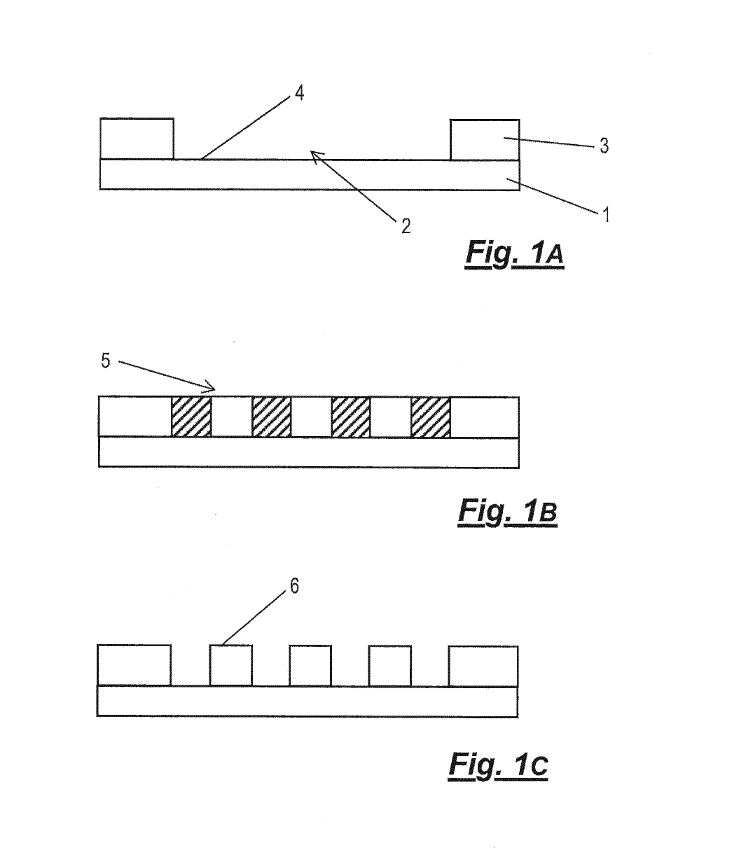

FIGS. 1A-C show the general principles of directed self-assembly and illustrate how directed self-assembly may be used to create lithographic features at very small dimensions. FIG. 1A shows a substrate 1 with a trench 2 formed thereon bounded by side-walls 3 and a bottom surface 4. In FIG. 1B, a self-assemblable A-B block copolymer with hydrophilic A blocks (hatched) and hydrophobic B blocks (unhatched) has been deposited into the trench to form a layer 5 with alternating stripes of A and B domains which have deposited as a lamellar phase separated into discrete micro-separated periodic domains during deposition of the BCP. In FIG. 1C, the type A domains have been removed by selective chemical etching, leaving the type B domains as a number of regularly spaced rows of lithography features 6.

Selective etching is achieved due the relative susceptibility towards etching, with the A block being relatively prone to etching, while the B block is relatively resistant to etching. Selective removal may also be achieved, for instance, by selective photo-degradation or photo-cleavage of a linking agent between blocks of the copolymer and subsequent solubilization of one of the blocks. An embodiment of the invention allows for formation, onto a substrate, of a row of regularly spaced lithography features, positioned side-by side along a substrate, using self-assembled BCP to provide features which are hence closely spaced and small in size.

In embodiment (not illustrated) the etching (or other removal process) may etch into the substrate 1. Following this the type B domains may be removed, leaving behind regularly spaced rows of lithography features formed in the substrate.

In an embodiment, the side-walls of the trench may have a higher chemical affinity for one of the BCP domain types. For example in a trench for aligning a di-block copolymer having A and B blocks, where A is hydrophobic and B is hydrophilic in nature, the trench may comprise a hydrophobic resist side-wall feature, with a neutral orientation base therebetween. The A domains may preferentially assemble alongside the hydrophobic resist feature, with several alternating domains of A and B blocks aligned over the neutral orientation base between the sidewalls of the trench.

Although in the above example the trenches are formed in resist, the trenches may be formed in any suitable material. For example, the trenches may be formed in the substrate (e.g., having been transferred from resist into the substrate). The trenches may be formed in a film stack deposited on the substrate surface.

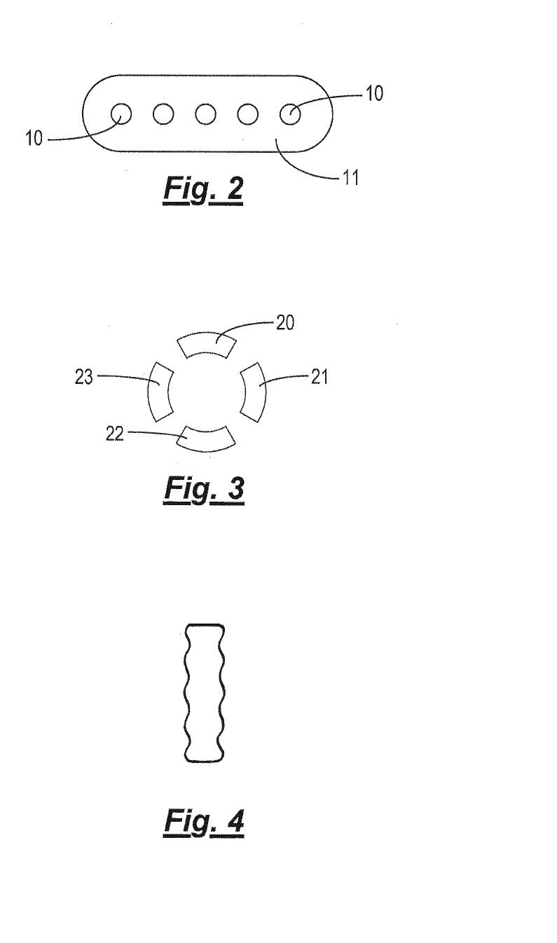

Directed self-assembly may be used to form a channel hole which may in a completed circuit be used to connect together electrically two or more layers of a semi-conductor structure. This may be achieved by surrounding a domain of one of A or B block with a domain of the other. For example, in the case of a PS-PMMA BCP, a domain of PMMA may be surrounded by a domain of PS. This principle may be extended to generate a row of contact holes as shown in FIG. 2 where five A domains 10 are surrounded by an elongate B domain 11. A difficulty with forming such a row of contact holes with the dimensions available using a self-assembly technique is that placement errors may become problematic. In particular, as the number of contact holes in the row increases, the possible placement error can increase.

In order to help mitigate this problem the pre-patterning of the substrate prior to forming the trench may be performed using off-axis illumination (i.e., illumination with high outer sigma and a narrow range of illumination angles) in order to introduce a modulation into a side wall of the trench such that the width of the trench varies along the length of the trench in a generally sinusoidal manner. In the self-assembly process this modulation serves to confine the BCP more accurately and thus to reduce placement errors in the contact holes (or other lithographic features that may be formed using a BCP technique).The illumination may be provided by actinic radiation, e.g. UV, DUV (deep ultra-violet) and/or EUV (extreme ultra-violet) radiation.

One possible method of applying off-axis illumination is to use C-Quad quadrupole illumination in which the incident radiation strikes the substrate from four part-annular regions 20, 21, 22 and 23, i.e. four poles, as shown in FIG. 3. One consequence of using off-axis illumination is that it is subject to diffraction effects known as “ringing” which results in intensity variations along vertical and horizontal features. In lithography generally such ringing is a problem and if the benefits of off-axis illumination are to be enjoyed, the negative effects of ringing must be compensated for in the pattern design. However, in embodiments of the present invention the phenomenon of ringing can be used advantageously as will be explained below.

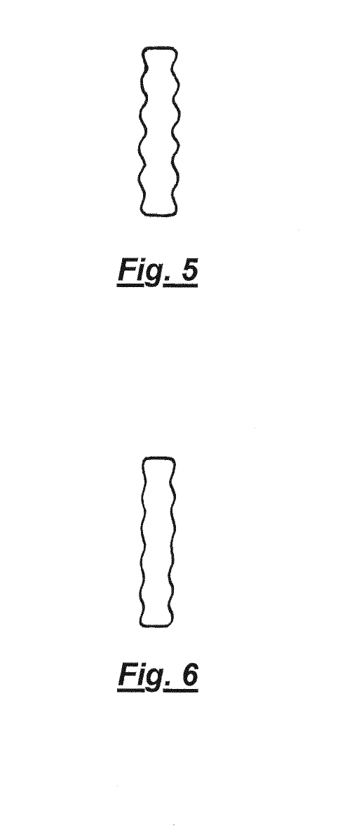

Referring firstly to FIG. 4 by using C-Quad quadrupole off-axis illumination to print the trench, a trench is formed in which a side-wall is not straight but the edge of which modulates at a regular frequency such that the width of the trench is not constant but oscillates between minimum and maximum values. The frequency of this modulation may be varied by changing the numerical aperture (NA) of the illumination system. In the example of FIG. 4, the NA is set at 1.1, whereas in the example of FIG. 5 the NA is set at 1.35 resulting in a higher frequency modulation. Similarly the amplitude of the modulation may be controlled by varying the intensity ratio of the poles of the C Quad illumination system. In the examples of FIGS. 4 and 5, one pair of poles has an illumination intensity that is 100× greater than the other pair. In the example of FIG. 6 the intensity ratio is reduced to 25:1 with a consequential decrease in the amplitude of the modulation which is significantly less pronounced. Depending on the amplitude desired for the modulation a range for the intensity ratio may be from 1:20 to 1:200.

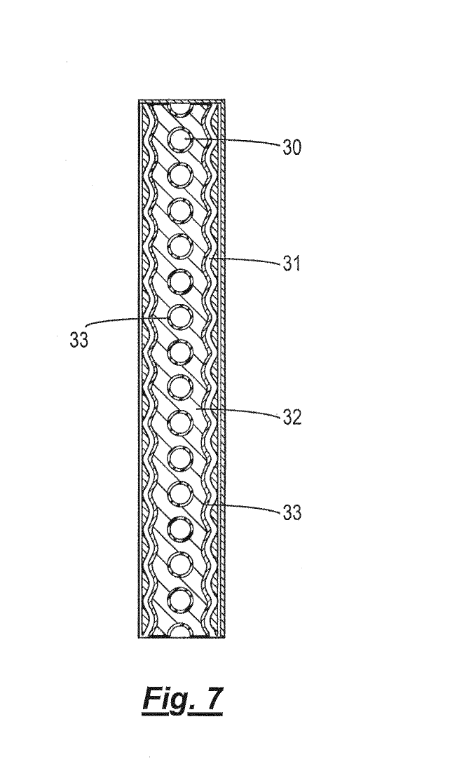

In embodiments, the frequency of the modulation may be selected such that the pitch of the modulation corresponds to a desired spacing between lithography features that are arranged in a row, e.g. channel holes. The trench may then be used as the basis for a directed self-assembly BCP process in which the domains which are to form the row of regular features will be located where the width of the trench is at a maximum. The placement of the lithography features will therefore be controlled by the modulation of the side wall of the trench and greater placement accuracy may be achieved. FIG. 7 shows an example of such a structure formed by a directed self-assembly process in accordance with an embodiment of the invention. In FIG. 7 a structure is shown of a regular spaced row of A domains 30 that will form the contact holes. Domains 30 are surrounded by B domain 32 but around each contact hole there will be a thin mixed phase 33. Also shown in FIG. 7 is a modulating edge domain 31 of the same type (i.e. A domain) as the domains 30.

Further embodiments are listed in the following numbered clauses:
1. A method of forming a plurality of regularly spaced lithography features, the method comprising:

providing a trench on a substrate, the trench comprising opposing side-walls and a base, with the side-walls having a width therebetween, wherein the trench is formed by photolithography including exposing the substrate using off-axis illumination whereby a modulation is provided to the side-walls of the trench such that the width of the trench varies between minimum and maximum values along the length of the trench;

providing a self-assemblable block copolymer having first and second blocks in the trench;

causing the self-assemblable block copolymer to self-assemble into an ordered layer in the trench, the layer comprising first domains of first block and second domains of second block; and

selectively removing the first domain to form at least one regularly spaced row of lithography features comprising the second domain along the trench.
2. The method as in embodiment 1, wherein the frequency of the modulation is controlled to match a desired pitch of the features.
3. The method as in embodiment 2, wherein the frequency of the modulation is controlled by varying the numerical aperture of a system providing the off-axis illumination.
4. The method as in embodiment 3, wherein the numerical aperture is in a range of from 1.1 to 1.35.
5. The method as in any of embodiments 1 to 4, wherein the off-axis illumination comprises quadrupole illumination.
6. The method as in embodiment 5, wherein the intensity of the modulation is controlled by varying the intensity ratio of two pairs of poles of the illumination.
7. The method as in embodiment 6, wherein the intensity ratio is in a range of from 1:20 to 1:200.
8. The method as in any of embodiments 1 to 7, wherein the lithography feature comprises a contact hole.
9. The method as in any of embodiments 1 to 8, wherein side-walls of the trench are formed to have a higher chemical affinity for one of the block co-polymer blocks.
10. The method as in any of embodiments 1 to 9, wherein the self-assemblable block co-polymer is adapted to form a regularly spaced row of the second domains surrounded by the first domain.
11. The method as in any of embodiments 1 to 10, wherein the first domain is removed by etching.
12. The method as in any of embodiments 1 to 11, wherein the first domain is removed by photo-degradation or photo-cleavage.
13. The method as in any of embodiments 1 to 12, wherein the trench is formed by exposure using UV, EUV or DUV radiation.
14. A semiconductor product provided with contact holes formed by the method of any of embodiments 1 to 13.
15. A trench on a substrate, the trench being at least partly filled with block co-polymer, the trench comprising a plurality of side-walls forming the contours of the trench, the side-walls including a first side-wall and a second side-wall, the first side-wall being shorter than the second side-wall, the second side-wall having a multi-curve structure and the first side-wall being substantially straight.
16. The trench of embodiment 15, wherein the first side-wall and the second side-wall touch.
17. The trench according to embodiment 15 or embodiment 16, further comprising a third side-wall opposite the second side-wall, the third side-wall having a multi-curve structure.
18. The trench according to any of embodiments 15 to 17, further comprising a fourth side-wall opposite the first side-wall, the fourth side-wall being substantially straight.
19. A trench on a substrate, the trench being at least partly filled with block co-polymer, the trench comprising opposing side-walls and a base, with the side-walls having a width therebetween, wherein the side-walls of the trench are such that the width of the trench varies between minimum and maximum values along the length of the trench.
20. The trench according to any of embodiments 15-18, wherein the substrate is a wafer.

Embodiments of the invention are suited for forming a contact hole but may also be useful in the formation of other types of regular lithography features. For example, the domains to form the contact holes may be elongated across the width of the trench to form elongated contact holes.

1. A method of forming a plurality of regularly spaced lithography features, the method comprising:
providing a trench on a substrate, the trench comprising opposing side-walls and a base, with the side-walls having a width therebetween, wherein the trench is formed by photolithography including exposing the substrate using off-axis illumination whereby a modulation is provided to a side-wall of the trench such that the width of the trench varies between minimum and maximum values along the length of the trench;
causing a self-assemblable block copolymer in the trench to self-assemble into an ordered layer in the trench, the layer comprising first domains of a first block of the self-assemblable block copolymer and second domains of a second block of the self-assemblable block copolymer; and
selectively removing the first domain to form at least one regularly spaced row of lithography features comprised of the second domain along the trench.

2. The method as claimed in claim 1, wherein the frequency of the modulation is controlled to match a desired pitch of the features.

3. The method as claimed in claim 2, wherein the frequency of the modulation is controlled by varying the numerical aperture of a system providing the off-axis illumination.

4. The method as claimed in claim 3, wherein the numerical aperture is in a range of from 1.1 to 1.35.

5. The method as claimed in claim 1, wherein the off-axis illumination comprises quadrupole illumination.

6. The method as claimed in claim 5, wherein the intensity of the modulation is controlled by varying an intensity ratio of two pairs of poles of the illumination.

7. The method as claimed in claim 6, wherein the intensity ratio is in a range of from 1:20 to 1:200.

8. The method as claimed in claim 1, wherein the lithography feature comprises a contact hole.

9. The method as claimed in claim 1, wherein side-walls of the trench are formed to have a higher chemical affinity for one of the block co-polymer blocks.

10. The method as claimed in claim 1, wherein the self-assemblable block co-polymer is adapted to form a regularly spaced row of the second domains surrounded by the first domain.

11. The method as claimed in claim 1, wherein the first domain is removed by etching.

12. The method as claimed in claim 1, wherein the first domain is removed by photo-degradation or photo-cleavage.

13. The method as claimed in claim 1, wherein the trench is formed by exposure using UV, EUV or DUV radiation.

14. A semiconductor product provided with contact holes formed by the method of claim 1.

15. A method, comprising:
forming a trench for self-assembly of a self-assemblable block copolymer in the trench by photolithography, the forming including exposing a substrate using off-axis illumination whereby a modulation is provided to a side-wall of the trench such that the width of the trench between opposing side-walls of the trench varies between minimum and maximum values along the length of the trench.

16. The method as claimed in claim 15, wherein the frequency of the modulation is controlled to match a desired pitch of the features.

17. The method as claimed in claim 16, wherein the frequency of the modulation is controlled by varying the numerical aperture of a system providing the off-axis illumination.

18. The method as claimed in claim 17, wherein the numerical aperture is in a range of from 1.1 to 1.35.

19. The method as claimed in claim 15, wherein the off-axis illumination comprises quadrupole illumination.

20. The method as claimed in claim 19, wherein the intensity of the modulation is controlled by varying an intensity ratio of two pairs of poles of the illumination.
